(19) United States
(12) Patent Application Publication
(10) Pub. No.: US 2010/0270143 A1
(43) Pub. Date: Oct. 28, 2010

(54) SUBSTRATE STAGE, SPUTTERING APPARATUS PROVIDED WITH SAME, AND FILM FORMING METHOD

(75) Inventors: Yukio Kikuchi, Chigasaki-shi (JP); Guo Hua Shen, Chigasaki-shi (JP)

Correspondence Address: GROSSMAN, TUCKER, PERREAULT & PFLEGER, PLLC, 55 SOUTH COMMERICAL STREET, MANCHESTER, NH, 03101, US

(73) Assignee: ULVAC, INC., Chigasaki-shi (JP)

(21) Appl. No.: 12/808,045

(22) PCT Filed: Jan. 15, 2009
(86) PCT No.: PCT/JP2009/050464

§ 371 Date: Jun. 14, 2010

(30) Foreign Application Priority Data
Jan. 15, 2008 (JP) P2008-005993
Feb. 7, 2008 (JP) P2008-027719

(51) Int. Cl. C23C 14/35

(52) U.S. Cl. 204/192.2; 204/298.16; 204/192.15; 257/E43.006

(57) ABSTRACT

A substrate stage that is arranged in a vacuum chamber and that has a substrate mounting surface on which a substrate is mounted, including a first magnetic field applying unit that applies a magnetic field to the substrate, in which the internal magnetization direction of the first magnetic field applying unit and the thickness direction of the substrate match.

### TECHNICAL FIELD

The present invention relates to a substrate stage, a sputtering apparatus provided with the substrate stage, and a film forming method.

Priority is claimed on Japanese Patent Application No. 2008-005993, filed Jan. 15, 2008, and Japanese Patent Application No. 2008-027719, filed Feb. 7, 2008, the contents of which are incorporated herein by reference.

### BACKGROUND ART

Conventionally, a sputtering apparatus is widely used as a preferred film formation processing apparatus for formation of a film that constitutes a semiconductor device such as a Tunneling Magnetic Resistive (TMR) that constitutes a Magnetic Random Access Memory (MRAM).

As such a sputtering apparatus, there is one that is constituted by disposing in a processing chamber a substrate stage on which a substrate is placed and a sputtering cathode that is disposed so as to be inclined with respect to the normal line of the substrate and that is provided with a target of a film formation material. In this sputtering apparatus, by performing a sputtering process while rotating the substrate stage, a good film quality uniformity is obtained. Also, a constitution is known that disperses plasma generated in the vicinity of the target until the vicinity of the substrate by intentionally breaking down the magnetic field from a cathode without causing the plasma to converge in the vicinity of the target in the manner of a conventional balanced magnetron cathode (for example, refer to Patent Document 1).

### Patent Document 1: Japanese Unexamined Patent Application No. 2000-282235

Patent Document 2: Japanese Unexamined Patent Application No. H06-264235

### DISCLOSURE OF THE INVENTION

### Problem that the Invention is to Solve

FIG. 1 is a cross-sectional view of a magnetic tunnel junction.

As shown in FIG. 1, a tunnel junction element 10 is constituted by laminating a magnetic layer (fixed layer) 14, a tunnel barrier layer (insulating layer) 15, and a magnetic layer (free layer) 16.

In MRAM of recent years, development has been proceeding of a perpendicular magnetic tunnel junction element 10 using a perpendicular magnetization film on the magnetic layers 14 and 16. The perpendicular magnetization format involves using magnetization rotation in a perpendicular direction that is hardly influenced by a demagnetizing field. With this method, further miniaturization of the element becomes possible, and it is possible to raise the recording density. For that reason, its adoption is considered indispensable for accomplishing the production of gigabit-class memory. Moreover, it is possible to obtain a large resistance change ratio (MR ratio), and it is expected to be a system that can reduce the write current to one divided by several tenths.

However, in the conventional perpendicular magnetic tunnel junction element 10, the actual performance is one in which the desired MR ratio described above has not been obtained. A cause of this is considered to be that dispersion in the magnetization direction of the magnetic layers 14 and 16 cannot fully be controlled. When conventionally forming a perpendicular magnetization film, since manufacturing is carried out by utilizing only the property of the magnetic layers 14 and 16 to be perpendicularly magnetized without applying a magnetic field in the magnetizing direction, there is a problem of a dispersion arising in the magnetizing direction of the magnetic layers 14 and 16 that are formed. As a result, in the film forming process of the magnetic films 14 and 16, a dispersion occurs in the film characteristics such as the crystal alignment properties of the magnetic layers 14 and 16, leading to the occurrence of variations of the film resistance value.

Also, the inside of the processing chamber that forms the magnetic layers 14 and 16 differs from the case of only one cathode being disposed in the processing chamber as disclosed in the aforementioned Patent Document 1, and normally a plurality of cathodes are disposed in the processing chamber, and film formation materials of different types are attached to each cathode target. For that reason, each cathode is disposed so as to incline with respect to the normal line of the substrate. In this case, a constitution that provides a permanent magnet and electromagnet on each cathode to apply a magnetic field in the thickness direction (normal direction) of the substrate is not realistic due to practical difficulties such as the constitution becoming increasingly complex.

Also, when forming the magnetic layers 14 and 16 of a perpendicular magnetization film described above, it is desirable to perform a sputtering process while applying a perpendicular magnetic field to the front surface of the substrate.

Therefore, by internally installing the magnetic field applying unit that consists of a permanent magnet in the substrate stage that mounts the substrate, a constitution is conceivable so as to perform sputtering film forming while applying a magnetic field that has a perpendicular magnetic field component to the surface of the substrate.

For example, a magnetic film forming device in which between the target and the substrate a Helmholtz coil is disposed on the periphery of the vacuum chamber (container) so that a magnetic field is applied in a perpendicular direction with respect to the substrate surface is known (refer to Patent Document 2). However, in this magnetic film forming device, as a result of disposing the Helmholtz coil on the periphery of the vacuum chamber, the problem arises of the device increasing in size.

FIG. 18 is a schematic configuration drawing that shows a substrate stage in which a magnetic field applying unit is internally installed.

As shown in FIG. 18, the substrate stage 300 is provided with a stage body 301 on which the substrate W is placed, and a plurality of elevating pins 302 (only one is shown in FIG. 18) that perform reception of the substrate W and transfer of the substrate W in the processing chamber. A magnetic field applying unit 303 that consists of a permanent magnet is internally installed in the stage body 301. The elevating pin 302 is inserted in a through hole 304 that passes through the stage body 301 in the thickness direction, and is constituted to be capable of vertical motion with respect to the stage body 301.

However, with this constitution, as a result of providing the elevating pins 302 in the stage body 301, it is necessary to form the through hole 304 that causes the elevating pins 302 to pass through the stage body 301 and the magnetic field applying unit 303. Accordingly, a space where the magnetic field applying unit 303 does not exist is formed in the through hole 304 to the extent of the outer diameter of the through hole 304.

In this case, magnetic lines of force B′ that are generated from the magnetic field applying unit 303 wrap around to the back surface side of the magnetic field applying unit 303 through the through hole 304. That is, at the region of the substrate W in the vicinity of the through hole 304, a dispersion occurs in the magnetic field direction that is applied on the front surface of the substrate W. Moreover, in the region in the middle of the through hole 304, a problem arises out of a magnetic field being applied that is opposite to that of the region surrounding the through hole 304. As a result, a dispersion of the magnetizing direction in the magnetic layers 214 and 216 occurs within the plane (refer to FIG. 12), which serves as a cause for triggering a drop in the MR ratio and a dispersion.

Therefore, the present invention is one that was achieved to solve the aforementioned issues, and has as its object to provide a substrate stage, a sputtering apparatus that is provided with the substrate stage, and a film forming method that can obtain a high MR ratio through suppressing dispersion in the magnetization direction of the magnetic layer by applying a perpendicular magnetic field to the total surface of the surface of a substrate, for example when forming a magnetic layer by the sputtering method.

### Means for Solving the Problem

In order to solve the aforementioned issues and achieve the aforementioned object, the substrate stage of the present invention is a substrate stage that is arranged in a vacuum chamber and that has a substrate mounting surface on which a substrate is mounted, provided with a first magnetic field applying unit that applies a magnetic field to the substrate, and in which the internal magnetization direction of the first magnetic field applying unit and the thickness direction of the substrate match.

The first magnetic field applying unit may be provided so as to encircle the periphery of the substrate that is mounted on the substrate mounting surface.

According to the aforementioned substrate stage, by providing the magnetic field applying unit so as to encircle the periphery of the substrate and making the internal magnetization direction of this magnetic field applying unit match the thickness direction of the substrate, it is possible to perform sputtering film formation while accurately applying a magnetic field that has a perpendicular magnetic field component to the front surface of the substrate.

The middle of the first magnetic field applying unit may be arranged at the same height as the front surface of the substrate in the normal line direction of the substrate mounting surface.

In this case, it is possible to increase the strength of the magnetic field component that is perpendicularly incident on the front surface of the substrate by arranging the front surface of the substrate at the middle portion of the magnetic field applying unit in the thickness direction of the substrate.

The first magnetic field applying unit having a size that is equal to or greater than the outer diameter of the substrate may be provided on the back surface side of the substrate that is mounted on the substrate mounting surface.

In this case, by providing the magnetic field applying unit that is formed to a size that is equal to or greater than the outer diameter of the substrate and making the internal magnetization direction of this magnetic field applying unit match the thickness direction of the substrate, it is possible to perform sputtering film formation while accurately applying a magnetic field that has a perpendicular magnetic field component to the front surface of the substrate.

A first magnetic body that is positioned between the first magnetic field applying unit and the substrate may further be provided.

In this case, since magnetic lines of force are arranged along the center axis in the first magnetic body by providing the first magnetic body between the magnetic field applying unit and the substrate, it is possible to improve the perpendicularity of the magnetic field that is incident on the front surface of the substrate.

A second magnetic body that is arranged so as to encircle the periphery of the substrate may further be provided.

In this case, since magnetic lines of force are arranged along the center axis on the inside of the second magnetic body by providing the second magnetic body so as to encircle the periphery of the substrate, it is possible to further improve the perpendicularity of the magnetic field that is incident on the front surface of the substrate.

The substrate stage may further comprise an elevating pin that raises and lowers the substrate with respect to the substrate mounting surface, and a second magnetic field applying unit that is provided in the elevating pin; in which the first magnetic field applying unit has a through hole, the elevating pin is inserted in a slidable manner in the through hole; and the internal magnetization direction of the second magnetic field applying unit and the internal magnetization direction of the first magnetic field applying unit match.

In this case, by providing the second magnetic field applying unit that has the same magnetization direction as the inside of the first magnetic field applying unit in the elevating pin, the second magnetic field applying unit that has the same magnetization direction as the inside of the first magnetic field applying unit comes to be interposed in the through hole that is formed in the stage body and the first magnetic field applying unit. Thereby, it is possible to reduce the region in which the magnetic field applying unit does not exist in the through hole. Accordingly, it is possible to apply a perpendicular magnetic field with respect to the entire surface of the front surface of the substrate.

In the state of the substrate being mounted on the substrate mounting surface, the upper end surface of the first magnetic field applying unit and the upper end surface of the second magnetic field applying unit may be capable of being arranged on the same plane.

In this case, since the respective upper end surfaces of the first magnetic field applying unit and the second magnetic field applying unit can be arranged on the same plane, it is possible to improve the perpendicularity of the magnetic field that is applied on the front surface of the substrate.

The substrate stage may be provided with a plurality of the elevating pins and a support member that mutually couples the elevating pins, in which the first magnetic field applying unit has a plurality of the through holes, and the elevating pins are respectively arranged in the through holes.

In this case, by coupling the elevating pins with the support members, it is possible to prevent the collapse of the elevating pins due to attraction and repulsion between the first magnetic field applying unit and the second magnetic field applying unit, and hindrance of the movement of the elevating pins.

The substrate stage may be further provided with a magnetic body that is positioned between the first magnetic field applying unit and the substrate and between the second magnetic field applying unit and the substrate.

In this case, since magnetic lines of force are arranged along the center axis at the inside of the magnetic body by providing the magnetic body between each magnetic field applying unit and the substrate, it is possible to improve the perpendicularity of the magnetic field that is applied on the front surface of the substrate.

The sputtering apparatus of the present invention consists of the substrate stage; a sputtering cathode that is arranged so as to be inclined with respect to the normal line of a substrate that is mounted on the substrate mounting surface; a sputtering chamber in which the substrate stage and the sputtering cathode are arranged; a vacuum exhaust unit that performs vacuum exhaust of the sputtering chamber; a gas supply unit that supplies a sputtering gas to the sputtering chamber; and a power supply that applies a voltage on the sputtering cathode.

In this case, after pumping down the sputtering chamber with a vacuum exhaust unit, sputtering gas is introduced from the gas supply unit to the sputtering chamber, and by applying a voltage on the targets from the power supply, plasma is generated. Thereupon, sputtering gas ions collide with the targets that are cathodes, and particles of a film formation material fly out from the targets and adhere to the substrate. By the above, it is possible to perform sputtering film formation on the front surface of the substrate.

Also, since it is provided with the substrate stage of the present invention mentioned above, it is possible to apply a perpendicular magnetic field to the entire surface of the front surface of the substrate. Accordingly, it is possible to perform sputtering film formation while accurately applying a magnetic field that has a perpendicular magnetic field component to the front surface of the substrate. For that reason, in for example the film formation step of the magnetic layer, it is possible to perform film formation while aligning the magnetization direction of the magnetic layer in a perpendicular direction to the front surface of the substrate over the entire surface of the substrate. Thereby, since it is possible to improve the perpendicularity of the magnetization direction in the surface of the magnetic layer, it is possible to suppress dispersion in the magnetization direction in the surface of the magnetic layer. Accordingly, since it is possible to form a magnetic multilayer film with improved uniformity in the magnetization direction of the magnetic layer, it is possible to provide a tunnel junction element with a high MR ratio.

The film forming method of the present invention, with respect to a substrate that is mounted on a substrate stage that is arranged in a vacuum chamber and that has a substrate mounting surface on which a substrate is mounted, performs a sputtering process on the front surface of the substrate while applying a magnetic field with a first magnetic field applying unit so that the internal magnetization direction of this first magnetic field applying unit and the thickness direction of the substrate match.

The first magnetic field applying unit may be provided so as to encircle the periphery of the substrate.

In this case, by applying a magnetic field in the thickness direction of the substrate with the magnetic field applying unit, it is possible to perform sputtering film formation while accurately applying a magnetic field that has a perpendicular magnetic field component to the front surface of the substrate.

The first magnetic field applying unit may be provided on the back surface side of the substrate, and have a size that is equal to or greater than the outer diameter of the substrate.

In this case, by applying a magnetic field in the thickness direction of the substrate with the magnetic field applying unit that is formed to a size that is equal to or greater than the outer diameter of the substrate, it is possible to perform sputtering film formation while accurately applying a magnetic field that has a perpendicular magnetic field component to the front surface of the substrate.

Applying a magnetic field on the substrate by a second magnetic field applying unit that is provided in an elevating pin that is inserted in a slidable manner in a through hole that is provided in the first magnetic field applying unit and that raises and lowers the substrate with respect to the substrate mounting surface, matching the internal magnetization direction of the first magnetic field applying unit and the internal magnetization direction of the second magnetic field applying unit, and a sputtering process on the substrate with the upper end surface of the first magnetic field applying unit and the upper end surface of the second magnetic field applying unit arranged on the same plane may be performed.

In this case, by providing in the elevating pins the second magnetic field applying unit that has the same magnetization direction as the first magnetic field applying unit, and the respective upper end surfaces of the first magnetic field applying unit and the second magnetic field applying unit being arranged on the same plane, the second magnetic field applying unit that has the same magnetization direction as the inside of the first magnetic field applying unit comes to be interposed in the through hole that is formed in the stage body and the first magnetic field applying unit. Thereby, it is possible to reduce the space in which the magnetic field applying unit does not exist in the through hole. Accordingly, it is possible to perform a sputtering process in the state of applying a perpendicular magnetic field with respect to the entire surface of the front surface of the substrate.

Also, the film forming method of the present invention is characterized by using the aforementioned film formation method to form a perpendicular magnetization film for forming a tunnel junction element.

In this case, since it is possible to perform sputtering film formation while accurately applying a magnetic field that has a perpendicular magnetic field component to the front surface of the substrate, it is possible to perform film formation while aligning the magnetization direction of the perpendicular magnetization film with the perpendicular direction to the front surface of the substrate. Thereby, since it is possible to improve the perpendicularity of the magnetization direction of the perpendicular magnetization film, it is possible to suppress dispersion in the magnetization direction of the perpendicular magnetization film. Accordingly, since it is possible to form a magnetic multilayer film with improved film characteristics of the perpendicular magnetization film, crystalline orientation property, and uniformity in the magnetization direction, it is possible to provide a tunnel junction element with a high MR ratio.

### EFFECT OF THE INVENTION

According to the present invention, by matching the internal magnetization direction of the magnetic field applying unit with the thickness direction of the substrate, it is possible to perform sputtering film formation while accurately applying a magnetic field that has a perpendicular magnetic field component to the front surface of the substrate. Thereby, in for example the film formation step of the magnetic layer, it is possible to perform film formation while aligning the magnetization direction of the perpendicular magnetization film to be perpendicular to the front surface of the substrate. Thereby, since it is possible to improve the perpendicularity of the magnetization direction of the perpendicular magnetization film, it is possible to suppress dispersion in the magnetization direction of the magnetic layer. Accordingly, since it is possible to form a magnetic multilayer film with improved film characteristics and crystalline orientation property of the perpendicular magnetization film, it is possible to provide a tunnel junction element with a high MR ratio.

Also, according to the present invention, by providing the second magnetic field applying unit that has the same magnetization direction as the inside of the first magnetic field applying unit in the elevating pin, the second magnetic field applying unit that has the same magnetization direction as the inside of the first magnetic field applying unit comes to be interposed in the through hole that is formed in the stage body and the first magnetic field applying unit. Thereby, it is possible to reduce the space in which the magnetic field applying unit does not exist in the through hole. Accordingly, it is possible to apply a perpendicular magnetic field with respect to the entire surface of the front surface of the substrate.

### BRIEF DESCRIPTION OF THE DRAWINGS

FIG. 1 is a cross-sectional view of a tunnel junction element.

FIG. 2 is a schematic configuration drawing of the tunnel junction element manufacturing device in the first embodiment of the present invention.

FIG. 3A is a perspective view of the sputtering apparatus according to the first embodiment.

FIG. 3B is a side cross-sectional view of the sputtering apparatus according to the first embodiment.

FIG. 4 is an essential portion cross-sectional view of the magnetic field applying unit in the first embodiment.

FIG. 5A is an essential portion perspective view of the magnetic field applying unit in the second embodiment of the present invention.

FIG. 5B is an essential portion cross-sectional view of the magnetic field applying unit in the second embodiment of the present invention.

FIG. 6 is an essential portion cross-sectional view of the magnetic field applying unit in the third embodiment of the present invention.

FIG. 7 is an essential portion cross-sectional view of the magnetic field applying unit in the fourth embodiment of the present invention.

FIG. 8 is an explanatory diagram.

FIG. 9 is a graph that shows the uniformity of parallelism) (°) in the distance from the center of the substrate (mm).

FIG. 10 is a plan view that shows another constitution of the magnetic field applying unit in the present invention.

FIG. 11 is a plan view that shows another constitution of the substrate in the present invention.

FIG. 12 is a cross-sectional view of a tunnel junction element.

FIG. 13 is a schematic configuration drawing of a tunnel junction element manufacturing device in the fifth embodiment of the present invention.

FIG. 14A is a perspective view of the sputtering apparatus in the fifth embodiment.

FIG. 14B is a side cross-sectional view along line A-A′ of the sputtering apparatus according to the fifth embodiment.

FIG. 15 is a perspective view of the substrate stage in the fifth embodiment of the present invention.

FIG. 16 is a cross-sectional view that corresponds to the line C-C′ of FIG. 15.

FIG. 17 is an explanatory diagram that explains the magnetic lines of force that are generated from the magnetic field applying unit.

FIG. 18 is a schematic configuration drawing that shows a substrate stage with an internally installed magnetic field applying unit.

### DESCRIPTION OF REFERENCE NUMERALS

W substrate
23 sputtering apparatus
62 table
64 target
65, 100, 105 permanent magnet (magnetic field applying unit)
101 magnetic body (first magnetic body)
103 yoke (second magnetic body)
73 sputtering gas supply unit (gas supply unit)
222 sputtering apparatus
238 first magnetic field applying unit
239 first magnetic body (magnetic body)
240 through hole
242 second magnetic fiend applying unit
243 second magnetic body (magnetic body)
244 support member
262 substrate stage
265 sputtering cathode
273 sputtering gas supply unit (gas supply unit)

### BEST MODE FOR CARRYING OUT THE INVENTION

Next, the sputtering apparatus and film forming method according to the embodiments of the present invention shall be described with reference to the drawings. In each drawing that is used in the following description, the scale of each member is suitably changed in order to make each member a size that is recognizable.

### First Embodiment

### (Magnetic Multilayer Film)

First, a tunnel junction element that is used in MRAM, which is an example of a multilayer film that includes a magnetic layer, shall be described.

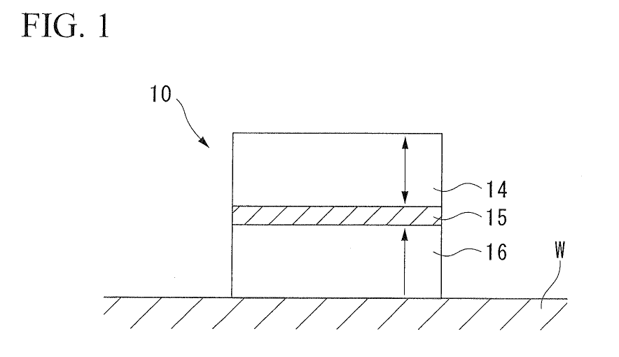

FIG. 1 is a side cross-sectional view of a tunnel junction element.

The tunnel junction element 10 is a perpendicular magnetic tunnel junction element 10 in which a magnetic layer (fixed layer) 16, a tunnel barrier layer 15 that consists of MgO or the like, a magnetic layer (free layer) 14, and an antiferromagnetic layer (not illustrated) consisting of PtMn or IrMn or the like are chiefly laminated on a substrate W. Note that for the constituent material of the magnetic layers 14 and 16, it is possible to adopt for example FePt, TbFeCo, Co/Pd, Fe/EuO, Co/Pt, Co/Pd, CoPtCr—SiO₂, CoCrTaPt, CoCrPt or the like. The tunnel junction element 10 is actually stacked with functional layers other than the aforementioned to become a multilayer structure of as many as 15 layers.

The magnetic layer (fixed layer) 14 is a layer that is fixed so that the magnetizing direction is perpendicular to the front surface of the substrate W, and specifically is fixed facing upward with respect to the front surface of the substrate W. On the other hand, the magnetic layer (free layer) 14 is a layer in which the magnetization direction changes with respect to the orientation of the external magnetic field, and can be inverted to parallel or anti-parallel with respect to the magnetization of the magnetic layer (fixed layer) 14. As a result of the magnetization direction of the fixed layer 16 and the free layer 14 being parallel or anti-parallel, the resistance value of the tunnel junction element 10 changes. By providing this kind of tunnel junction element 10 in an MRAM (not illustrated), since it is possible to impart “0”, “1” information in the magnetization direction of a magnetic body, it is possible to read and rewrite “1” or “0”.

### (Magnetic Multilayer Film Manufacturing Device)

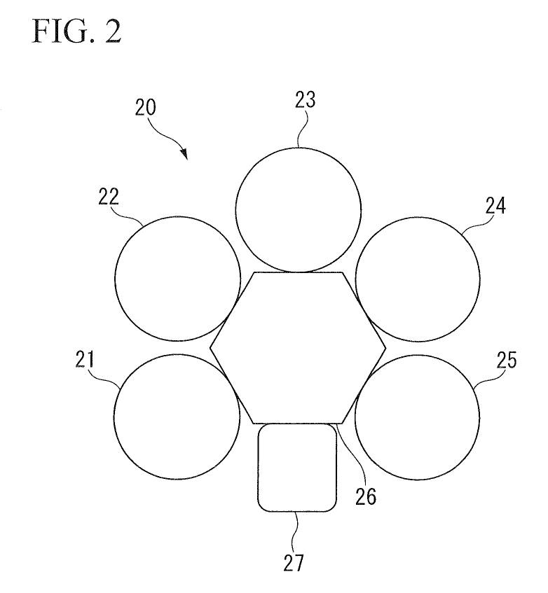

FIG. 2 is a schematic configuration drawing of a magnetic multilayer film manufacturing device according to the present embodiment (hereinbelow referred to as a manufacturing device).

As shown in FIG. 2, a manufacturing device 20 of the present embodiment is one in which a plurality of sputtering apparatuses 21 to 24 are arranged in a radial manner centered on a substrate conveying chamber 26, and for example is a cluster-type manufacturing device 20 that consistently performs a preprocessing/film formation step of a magnetic multilayer film that constitutes the aforementioned tunnel junction element.

Specifically, the manufacturing device 20 is provided with a substrate cassette chamber 27 in which a substrate W prior to film formation is held, a first sputtering apparatus 21 that performs the film formation step of the antiferromagnetic layer, a sputtering apparatus (second sputtering apparatus) 22 that performs the film formation step of the magnetic layer (fixed layer) 16, a third sputtering apparatus 23 that performs the film formation step of the tunnel barrier layer 15, and a sputtering apparatus (fourth sputtering apparatus) 24 that performs the film formation step of the magnetic layer (free layer) 16. Also, a substrate preprocessing device 25 is provided on the conveying side of the sputtering apparatus 24 via the substrate conveying chamber 26.

In the aforementioned manufacturing device 20, after the required substrate preprocessing, the magnetic multilayer film of the magnetic layer 16, the tunnel barrier layer 15, the magnetic layer 14, and the like is formed on the substrate W in the sputtering apparatuses 21 to 24. In this way, in the cluster-type manufacturing device 20, it is possible to form the magnetic multilayer film on the substrate W without exposing the substrate W that is supplied to the manufacturing device 20 to the atmosphere. Note that after forming a resist pattern on the magnetic multilayer film and patterning the magnetic multilayer film into a predetermined shape by etching, by removing the resist pattern the tunnel junction element 10 is formed.

Here, the sputtering apparatuses 22 and 24, which are sputtering apparatuses according to the present embodiment, that perform the film formation steps of the magnetic layers 14 and 16 in the magnetic multilayer film shall be described. Note that since the sputtering apparatuses 22 and 24 of the present embodiment have approximately the same constitution, in the following description only the sputtering apparatus 22 shall be described, and the description of the sputtering apparatus 24 shall be omitted.

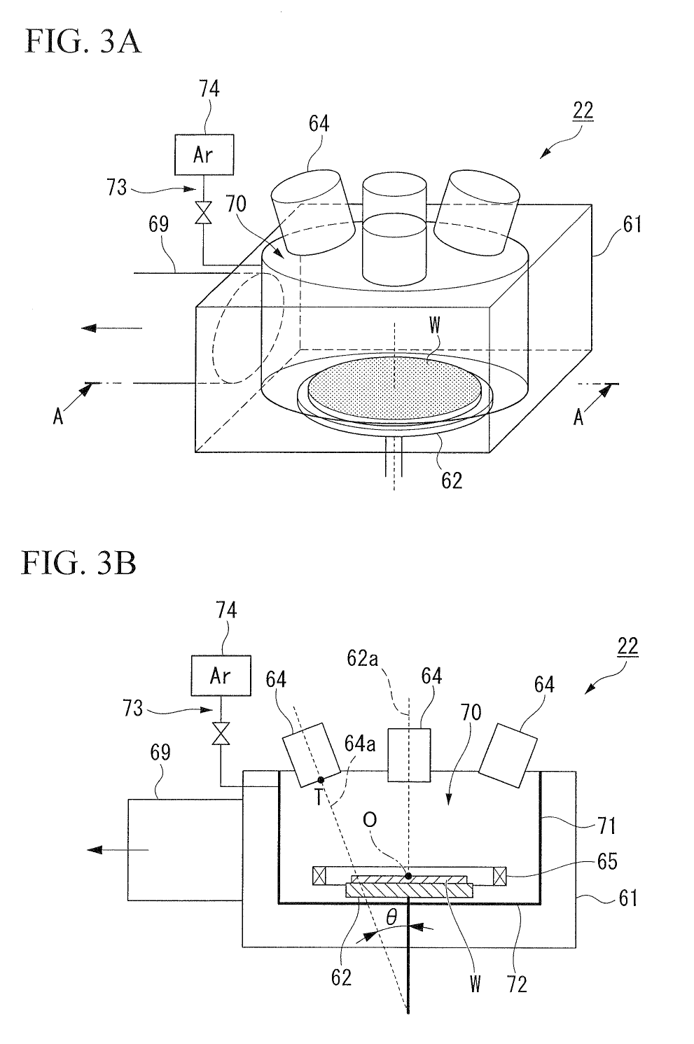

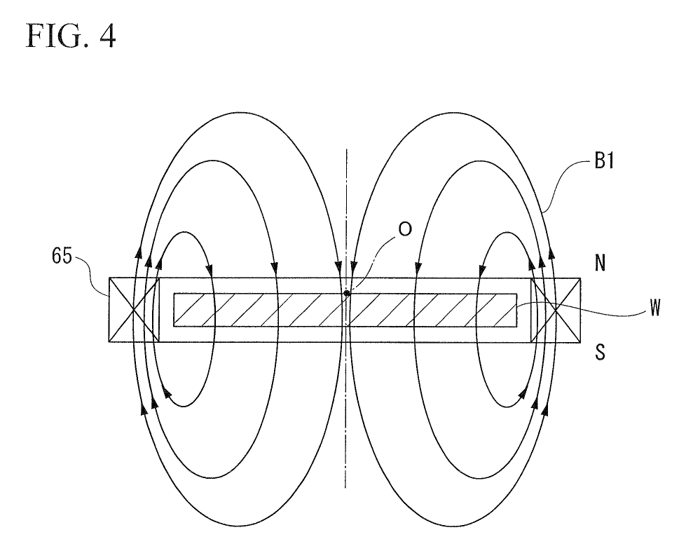

FIG. 3A is a perspective view of the sputtering apparatus according to the present embodiment, and FIG. 3B is a side cross-sectional view along line A-A in FIG. 3A. Also, FIG. 4 is an essential portion cross-sectional view.

As shown in FIG. 3A and FIG. 3B, the sputtering apparatus 22 is constituted by arranging at predetermined positions a table 62 on which the substrate W is mounted and a target 64. In the sputtering apparatus 22, the substrate W that has passed through the film formation step of the antiferromagnetic layer in the aforementioned first sputtering apparatus 21 is conveyed from the substrate conveying chamber 26 via a carry-in entrance that is not illustrated.

As shown in FIG. 3B, the sputtering apparatus 22 is provided with a chamber 61 that is formed in a box shape with a metallic material such as an Al alloy or stainless steel. The table 62 that mounts the substrate W is provided in the center portion in the vicinity of the bottom surface of the chamber 61. The table 62 is constituted to be rotatable at a given rotatational frequency with a rotating mechanism not illustrated, with a rotating shaft 62a and the center O of the substrate W coinciding. Thereby, the substrate W that is mounted on the table 62 can be made to rotate parallel to the surface thereof. Note that as for the substrate W of the present embodiment, a silicon wafer is used in which the substrate size is for example an outer diameter of 300 mm.

A shield plate that consists of stainless steel or the like (a side shield plate 71 and a bottom shield plate 72) are provided so as to encircle the aforementioned table 62 and the target 64. The side shield plate 71 is formed in a cylindrical shape and is disposed so that the center axis thereof coincides with the rotating shaft 62a of the table 62. Also, the bottom shield plate 72 is provided from the bottom end portion of the side shield plate 71 to the perimeter edge of the table 62. The bottom shield plate 72 is formed parallel with the front surface of the substrate W, and is disposed so that the center axis thereof coincides with the rotating shaft 62a of the table 62.

The space that is surrounded by the table 62, the bottom shield plate 72 and the side shield plate 71, and the ceiling surface of the chamber 61 is formed as a sputtering process chamber 70 (sputtering chamber) that performs the sputtering process on the substrate W. This sputtering process chamber 70 has an axially symmetric shape, and the axis of symmetry thereof agrees with the rotating shaft 62a of the table 62. Thereby, it is possible to perform a uniform sputtering process on each portion of the substrate W, and it is possible to reduce variation in the film thickness uniformity.

A sputtering gas supply unit (gas supply unit) 73 that supplies sputtering gas is connected to the upper portion of the side shield plate 71 that forms the sputtering process chamber 70. This sputtering gas supply unit 73 is one that introduces a sputtering gas such as argon (Ar) to the sputtering process chamber 70, and is constituted so that the sputtering gas is supplied from a sputtering gas supply source 74 that is provided outside of the sputtering process chamber 70. Note that it is also possible to supply a reactant gas such as O₂ from the sputtering gas supply unit 73. Also, a port 69 is provided in the side surface of the chamber 61. This port 69 is connected to an exhaust pump (exhaust unit) that is not illustrated.

At the periphery of the chamber 61 in the vicinity of the ceiling surface, a plurality of (for example, four) targets 64 are disposed at equally-spaced intervals along the circumference of the rotating shaft 62a of the table 62 (the circumferential direction of the substrate W). Each target 64 is connected to an external power supply (power supply) that is not shown, and is maintained at a negative electric potential (cathode).

A plurality of types of film formation materials that can be laminated on a magnetic multilayer film, such as the film formation material of the magnetic layer 14 described above and a film formation material of a foundation film are respectively disposed on the surface of each target 64. Note that the film formation material that is arranged on each target 64 may be suitably altered. Also, a constitution is also possible that arranges the film formation materials of the magnetic layers 14 and 16 on all of the targets 64.

Also, the aforementioned targets 64 are arranged so as to slant with respect to the normal line of the substrate W that is placed on the table 62.

Also, the targets 64 are arranged so that the normal line (center axis) 64a that passes through the center point T of the surface thereof slope for example at an angle θ with respect to the rotating shaft 62a of the substrate W, and the normal lines 64a of the targets 64 and the front surface of the substrate W intersect at the circumferential edge portion of the substrate W.

As shown in FIG. 4, a circular permanent magnet (magnetic field applying unit) 65 is arranged on the outer side of the substrate W in the radial direction so as to enclose the periphery of the substrate W. This permanent magnet 65 is one that is formed so that the inner diameter and thickness thereof are larger than the substrate W, and the internal magnetization direction of the permanent magnet 65 coincides with the thickness direction (normal direction) of the substrate W. It is constituted so that the substrate W is disposed in the middle portion of the permanent magnet 65 in the axial direction. That is, the front surface of the substrate W comes to be disposed in the middle portion of the permanent magnet 65 in the normal direction of the substrate W. Thereby, the magnetic lines of force B1 that extend from the permanent magnet 65 are generated from the N pole (for example, the top surface side), pass through the center hole, and after crossing perpendicularly through the front surface of the substrate W, head to the S pole (for example, the bottom surface side). Accordingly, the magnetic lines of force B1 that extend at the inner side of the permanent magnet 65 have a perpendicular (normal direction) magnetic field component with respect to the front surface of the substrate W, and are incident in an approximately perpendicular manner on the entire surface of the front surface of the substrate W. Note that in the present embodiment, the magnetic field applying unit was described as a circular permanent magnet, but provided it is a constitution that encloses the periphery of the substrate, it may be constituted by separately providing a plurality of permanent magnets.

### (Film Forming Method)

Next, the film forming method by the sputtering apparatus of the present embodiment shall be described. Note that in the following description, of the aforementioned magnetic multilayer film, the film forming method of the magnetic layer 14 by the sputtering apparatus 22 shall chiefly be described.

First, as shown in FIG. 3A and FIG. 3B, the substrate W is placed on the table 62, and the table 62 is made to rotate at a predetermined rotatational frequency with a rotating mechanism. After vacuuming the sputtering process chamber 70 with a vacuum pump, sputtering gas such as argon is introduced from the sputtering gas supply unit 73 to the sputtering process chamber 70. By applying a voltage on the targets 64 from the external power supply that is connected to the targets 64, plasma is generated. Thereupon, sputtering gas ions collide with the targets 64 that are cathodes, and particles of a film formation material fly out from the targets 64 and adhere to the substrate W. By the above, the magnetic layer 14 is formed on the front surface of the substrate W (refer to FIG. 1). At that time, by generating a high-density plasma in the vicinity of the targets 64, it is possible to speed up the film formation process.

The perpendicular magnetic tunnel junction element as described above uses switching the direction of magnetization in a perpendicular direction that is hardly influenced by a demagnetizing field. With this method, greater miniaturization of the element is possible, and since it is possible to increase the recording density, its adoption is considered indispensable for accomplishing the production of gigabit-class memory. Moreover, it is possible to obtain a high MR ratio, and will serve as art that can reduce the write current to one divided by several tenths. However, in the film formation step of a magnetic layer, the desired MR ratio is not obtained due to the effect of the dispersion in the magnetization direction of the magnetic layers 14 and 16 that are formed.

Therefore, in the present embodiment, in the film formation step of a magnetic layer 14, film formation is performing while generating a perpendicular magnetic field to the front surface of the substrate W with the permanent magnet 65 provided around the substrate W.

As shown in FIG. 4, when a magnetic field is applied by the permanent magnet 65, the magnetic lines of force B1 that extend from the permanent magnet 65 are perpendicularly incident on the entire surface of the front surface of the substrate W. Specifically, the magnetic lines of force B1 that extend at the inner side of the permanent magnet 65 are generated from the N pole (the top surface side), pass through the inner side of the permanent magnet 65 and are incident on the S pole (bottom surface side). The film formation material of the magnetic layer 14 that has flown out from the targets 64 comes to be deposited on the front surface of the substrate W while receiving the magnetic field that is perpendicular to the front surface of the substrate W. Note that the magnetic field that is applied by the permanent magnet 65 is preferably 50 (Oe) or more at each portion of the front surface of the substrate W.

As a result, in the film formation step of the magnetic layer 14, it is possible to perform film formation so that the magnetization direction of the magnetic layer 14 comes to be perpendicular with respect to the front surface of the substrate W. In this case, it is possible to constrict the parallelism (the definition of parallelism will be given below) of the magnetic layer 14 to 1 degree or less. Note that depending the film formation material to be used, it is preferable to set the annealing condition in order to improve the perpendicularity of the magnetic layer 14.

In this way, the present embodiment has a constitution that provides the permanent magnet 65 so as to surround the periphery of the substrate W and makes the internal magnetization direction of the permanent magnet 65 agree with the normal direction of the substrate W.

According to this constitution, by providing the permanent magnet 65 that has the magnetization direction in the normal direction of the substrate W, it is possible to perform sputtering film formation while accurately applying a magnetic field that has a perpendicular magnetic field component to the front surface of the substrate W. For that reason, in the film formation step of the magnetic layer 14, it is possible to perform film formation while aligning the magnetization direction of the magnetic layer 14 to be perpendicular to the surface of the substrate W. Thereby, since it is possible to improve the perpendicularity of the magnetization direction of the magnetic layer 14, it is possible to suppress dispersion of the magnetization direction of the magnetic layer 14. Accordingly, since it is possible to form a magnetic multilayer film with improved film characteristics and crystalline orientation property of the magnetic layer 14, it is possible to provide a tunnel junction element 10 with a high MR ratio.

By arranging the front surface of the substrate W in the middle of the permanent magnet 65 in the normal direction of the substrate W, it is possible to increase the magnetic field component that is perpendicularly incident on the surface of the substrate W. Accordingly, it is possible to further reduce dispersion in the magnetization direction of the magnetic layer 14.

Thereby, it is possible to provide the tunnel junction element 10 with a high MR ratio and a low write current without making the constitution of the sputtering apparatus 22 complex.

### Second Embodiment

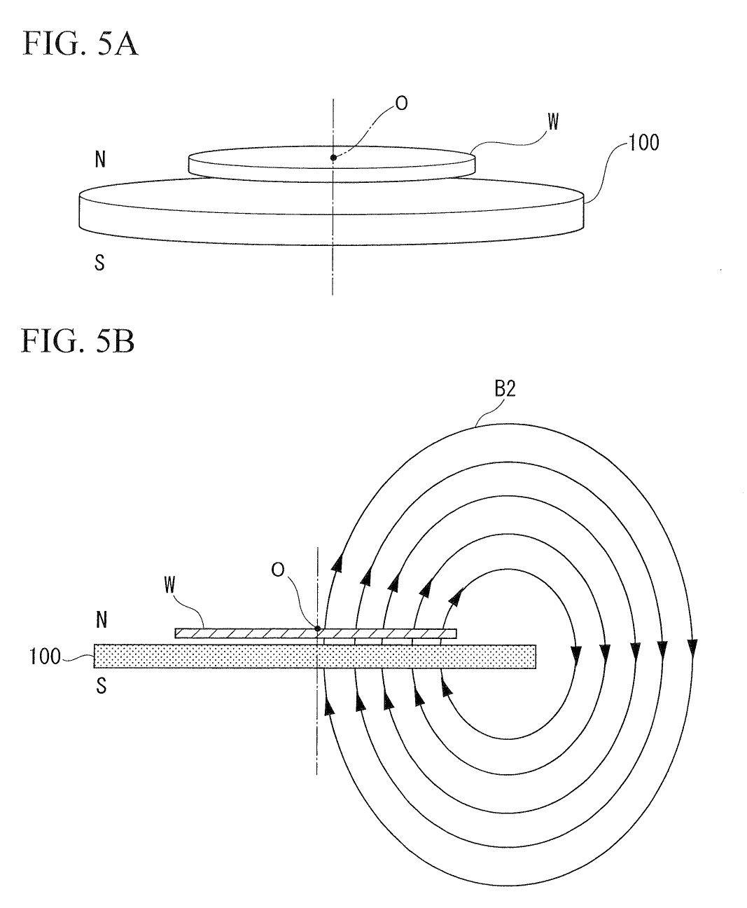

Next, the second embodiment of the present invention shall be described. In the present embodiment, the constitution of the magnetic field applying unit differs from that of the first embodiment, and the same reference numerals are given to those constitutions that are the same as the first embodiment, with the descriptions thereof being omitted. FIG. 5A is an essential portion perspective view of the second embodiment, and FIG. 5B is a cross-sectional view thereof. Note that in order to make the description easy to understand in FIG. 5A and FIG. 5B, the aforementioned chamber 61 (refer to FIG. 3A and FIG. 3B) has not been included.

As shown in FIG. 5A and FIG. 5B, a permanent magnet 100 that is parallel to the back surface of the substrate W is arranged on the back surface side of the substrate W. This permanent magnet 100 has a circular shape, and is disposed so that the center axis thereof and the center O of the substrate W coincide. The internal magnetization direction of the permanent magnet 100 agrees with the thickness direction (normal direction) of the substrate W. Accordingly, the magnetic lines of force B2 that extend from the permanent magnet 100 are generated from the N pole (for example, the top surface side), and after crossing approximately perpendicular through the front surface of the substrate W, turn around the outer circumference of the substrate W, and head to the S pole (for example, the bottom surface side). At this time, the magnetic lines of force B2 have a perpendicular (normal direction) magnetic field component with respect to the front surface of the substrate W, and are perpendicularly incident on the entire surface of the front surface of the substrate W.

Also, the outer diameter of the permanent magnet 100 is formed to be greater than the outer diameter of the substrate W (for example, 300 mm). Note that a suitable design modification is possible provided the outer diameter of the permanent magnet is equal to or greater than the outer diameter of the substrate. Also, it is preferable that the permanent magnet be a single body, but it is also possible to constitute a permanent magnet equal to or greater than the outer diameter of the substrate using a plurality of permanent magnets. In this case, it is preferable that the interval between each permanent magnet is 1 mm or less.

In this way, in the present embodiment, the permanent magnet 100 having a size that is equal to or greater than the outer diameter of the substrate is provided on the back surface side of the substrate W, and the internal magnetization direction of this permanent magnet 100 is made to agree with the normal direction of the substrate W.

According to this constitution, it is possible to exhibit the same effect as the first embodiment described above. Also, by forming the outer diameter of the permanent magnet 100 to be equal to or greater than the outer diameter of the substrate W, it is possible to increase the perpendicularity of the magnetic lines of force B2 that are incident on the substrate W, that is, the magnetic field component that is perpendicular to the front surface of the substrate W.

### Third Embodiment

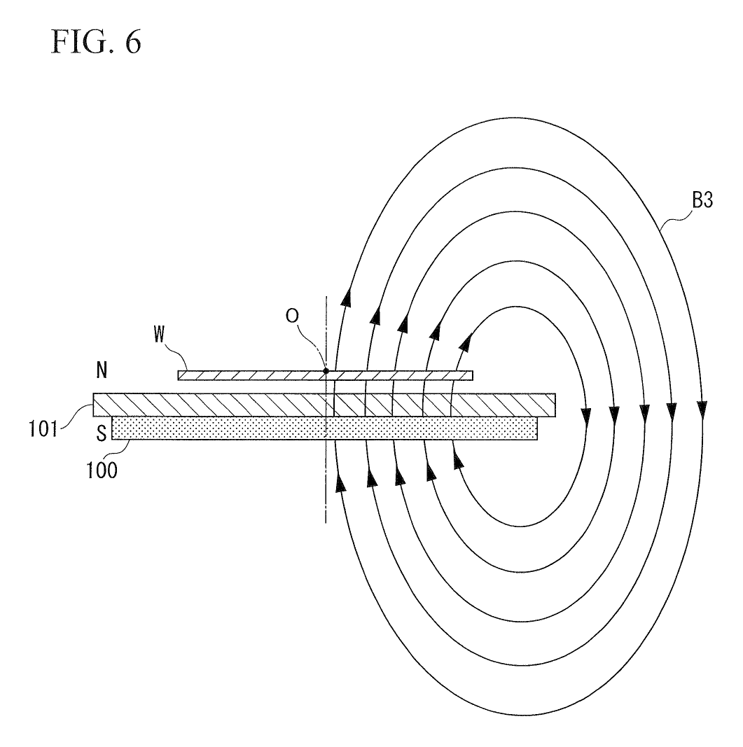

Next, the third embodiment of the present invention shall be described. The present embodiment differs from the second embodiment on the point of a first magnetic body being provided between the magnetic field applying unit and the substrate, and the same reference numerals are given to the same constitutions as the second embodiment, with the descriptions thereof being omitted. FIG. 6 is an essential portion cross-sectional view in the third embodiment. Note that in order to make the description easy to understand in FIG. 6, the aforementioned chamber 61 (refer to FIG. 3A and FIG. 3B) has not been included.

As shown in FIG. 6, a magnetic body (first magnetic body) 101 is provided on the permanent magnet 100. This magnetic body 101 is constituted from Fe that is nickel plated or magnetic stainless steel (SUS 430) or the like. The permanent magnet 100 has a disk shape, and is formed to be larger than the outer diameter of the permanent magnet 100.

In the present embodiment, the same effect is exhibited as the second embodiment described above, and by forming the magnetic body 101 on the permanent magnet 100, since magnetic lines of force are disposed along the center axis inside of the magnetic body 101, it is possible to improve the perpendicularity of the magnetic lines of force B3 that extend from the permanent magnet 100. That is, since it is possible to increase the magnetic field component that is perpendicular to the front surface of the substrate W, in the film forming step of the magnetic layers 14 and 16 (refer to FIG. 1), it is possible to further reduce dispersion of the magnetization direction of the magnetic layer 14.

### Fourth Embodiment

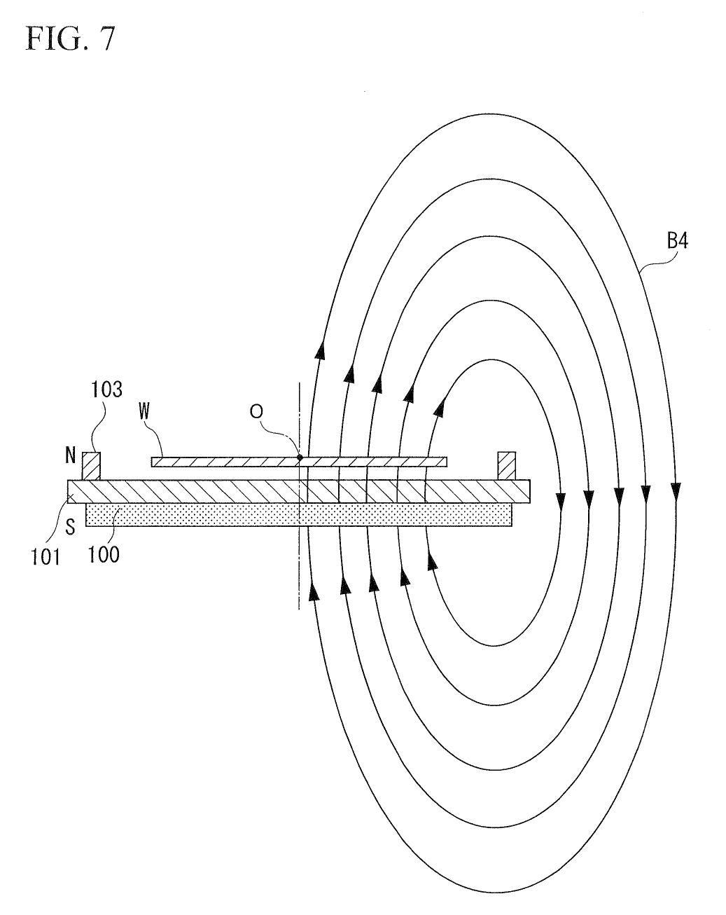

Next, the fourth embodiment of the present invention shall be described. The present embodiment differs from the second embodiment on the point of a second magnetic body being provided so as to enclose the periphery of the substrate, and the same reference numerals are given to those constitutions that are the same as the second embodiment, with the descriptions thereof being omitted. FIG. 7 is an essential portion cross-sectional drawing in the fourth embodiment. Note that in order to make the description easy to understand in FIG. 7, the aforementioned chamber 61 (refer to FIG. 3A and FIG. 3B) has not been included.

As shown in FIG. 7, a yoke (second magnetic body) 103 is provided on the magnetic body 101. This yoke 103 is constituted from Fe that is nickel plated or magnetic stainless steel (SUS 430) or the like similarly to the magnetic body 101 described above. The yoke 103 is formed so as to vertically rise up from the front surface of the magnetic body 101 at the outer circumference portion of the magnetic body 101, and is formed along the entire circumference of the magnetic body 101. Accordingly, the yoke 103 is disposed so as to encircle the periphery of the substrate W.

In the present embodiment, the same effect is exhibited as the second embodiment described above, and by disposing the yoke 103 on the magnetic body 101, since magnetic lines of force B4 are disposed along the center axis on the inner side of the yoke 103, it is possible to further improve the perpendicularity of the magnetic lines of force B4 that extend from the permanent magnet 100. That is, since it is possible to increase the perpendicular magnetic field component to the front surface of the substrate W, in the film forming step of the magnetic layer 14 (refer to FIG. 1), it is possible to further reduce dispersion of the magnetization direction of the magnetic layer 14.

### (Parallelism Measuring Experiment)

The inventors of the present application performed an experiment to measure the parallelism of the magnetic field with respect to the normal direction of the substrate using a sputtering apparatus provided with a magnetic field applying unit in the aforementioned embodiments. The measurement of parallelism in the present experiment was performed with a three-dimensional magnetic field measuring instrument using a Hall element at a position on the front surface of the substrate located about 5 mm away from the magnetic field applying unit. Also, at the measuring location of the magnetic field in the present invention, the magnetic field is considered to be axially symmetric with respect to the center of the substrate, and measurement is performed along the radial direction at a section extending from the center of the substrate on the front surface of the substrate to the outer circumference (a position about 2 mm from the outer circumferential edge). Note that the measurement is performed in two directions that are perpendicular on the substrate.

Note that the measurement conditions are as follows for each of the conditions A to C.

Condition A: Permanent magnet (outer diameter 300 mm, thickness 5 mm) only (same constitution as that of the second embodiment shown in FIG. 5A and FIG. 5B), Condition B: Permanent magnet (outer diameter 300 mm, thickness 5 mm)+magnetic body (Fe: outer diameter 300 mm, thickness 1.5 mm) (same constitution as that of the third embodiment shown in FIG. 6), Condition C: Permanent magnet (outer diameter 300 mm, thickness 5 mm)+magnetic body (Fe: outer diameter 300 mm, thickness 1.5 mm)+yoke (Fe: inner diameter 330 mm, width 20 mm, height 30 mm) (same constitution as that of the fourth embodiment shown in FIG. 7).

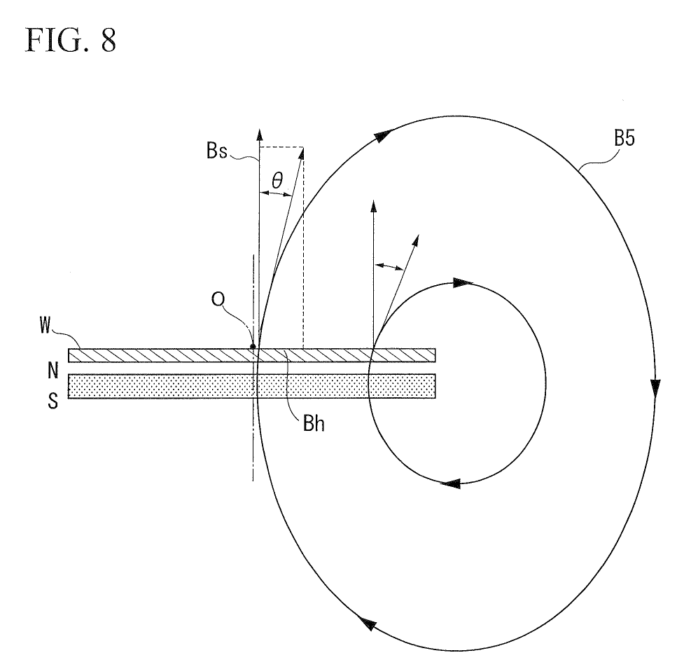

FIG. 8 is an explanatory diagram for the definition of the parallelism.

As shown in FIG. 8, the parallelism is an angle θ formed by the normal line that is perpendicular to the surface and the tangent direction of the magnetic line of force B0 at every point on the substrate W. That is, if the angle θ is 0°, it means a magnetic field that is perpendicular to the substrate W. In practice, assuming an axially symmetric coordinate system from the center O of the substrate, by measuring a magnetic field component Bs that is perpendicular to the front surface of the substrate W and a magnetic field component Bh that is parallel to the front surface of the substrate W, the angle θ is found from arctan (Bh/Bs).

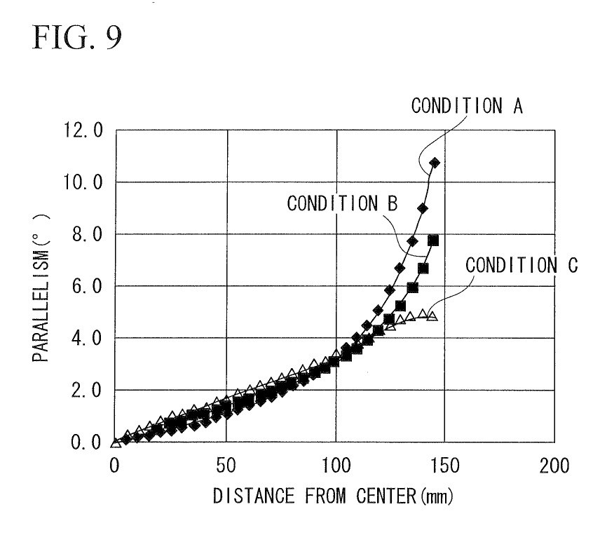

FIG. 9 shows the uniformity of the parallelism (°) in the distance (mm) from the center of the substrate.

As shown in FIG. 9, in the case of any of conditions A to C, heading from the center of the substrate (0 mm) to the outer circumference, the parallelism tends to improve, but in the case of condition A, at the outermost circumference of the substrate (148 mm), it was possible to restrict the parallelism to approximately 11°. Also, in the case of condition B, it was possible to restrict the parallelism to approximately 8°. This is considered to be due to the lines of force being disposed along the center axis at the inside of the magnetic body and an improvement in the perpendicularity of the lines of force extending from the permanent magnet, by arranging the magnetic body on the permanent magnet.

Moreover, in the case of condition C, it was possible to restrict the parallelism to approximately 5 mm at the outermost circumference of the substrate, and it was possible to significantly reduce the dispersion in the magnetization direction. This is considered to be due to the lines of force being disposed along the center axis at the inside of the yoke, and in particular to an improvement in the perpendicularity of the lines of force at the outer circumferential portion of the substrate by placing the yoke at the outer circumference portion of the magnetic body so as to surround the substrate.

From the above results, by applying a magnetic field that has a perpendicular magnetic field component to the front surface of the substrate with a permanent magnet as described above, it is possible to perform film formation while aligning the magnetization direction of the magnetic layer to be perpendicular to the front surface of the substrate, in for example the magnetic layer film formation process of the perpendicular magnetization method. Thereby, since it is possible to improve the film characteristics and crystalline orientation property of the magnetic film, and improve the perpendicularity of the magnetization direction of the magnetic layer, and it is possible to restrict dispersion of the magnetization direction of the magnetic layer, it is possible to obtain a high MR ratio.

Hereinabove, the preferred embodiments of the present invention were described with reference to the appended drawings, but needless to say the present invention is not limited to the examples. The constituent members and combinations shown in the above examples are one example, and various modifications are possible based on the design requirements within the scope that does not depart from the spirit of the present invention.

For example, in each of the aforementioned embodiments, a description was given for the case of using a permanent magnet as a magnetic field applying unit, but it is also possible to adopt a constitution so as to use an electromagnet instead of a permanent magnet. Also, in each of the aforementioned embodiments, a description was given for the case of forming a magnetic layer in the tunnel junction element of the magnetic multilayer film, but it can be adopted for various film formation materials without being limited to a magnetic layer.

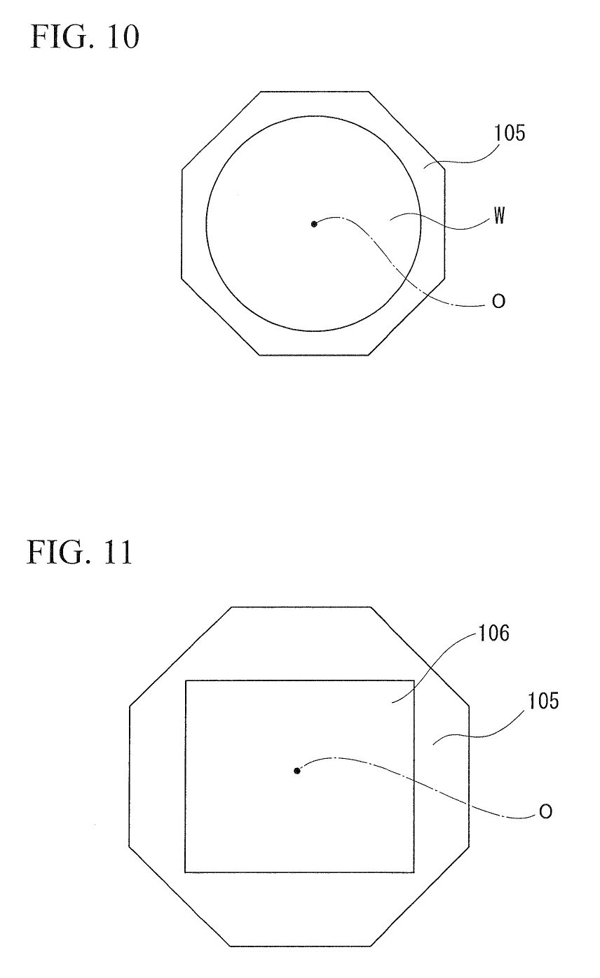

FIGS. 10 and 11 are plan views that show other constitutions of the magnetic field applying unit.

In each of the above embodiments, a description was given for the case of using a circular disk-shaped or ring-shaped permanent magnet, but as shown in FIG. 10, an appropriate design modification is possible such as using a rectangular permanent magnet 105. Also, in each of the above embodiments, a description was given for the case of using a disk-shaped substrate W (for example, refer to FIG. 3A and FIG. 3B), but as shown in FIG. 11, an appropriate design modification is possible such as using a rectangular substrate 106. Note that in any of the constitutions of FIG. 10 and FIG. 11, setting the outer diameter of the permanent magnet 105 to be equal to or greater than the outer diameter of the substrate W is preferable from the standpoint of improving the perpendicularity of the magnetic field.

### Fifth Embodiment

Next, the fifth embodiment of the present invention shall be described with reference to the drawings. Note that in each drawing that is used in the following description, the scale of each member is suitably changed in order to make each member a size that is recognizable.

### (Magnetic Multilayer Film)

First, a tunnel junction element that is used in MRAM, which is an example of a multilayer film that includes a magnetic layer, shall be described.

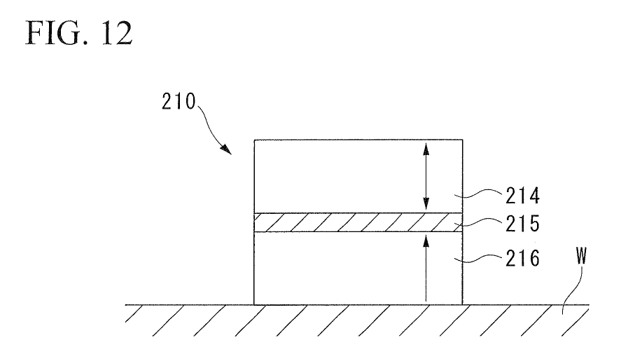

FIG. 12 is a side cross-sectional view of a tunnel junction element.

The tunnel junction element 210 is a perpendicular magnetic tunnel junction element 210 in which a magnetic layer (fixed layer) 216, a tunnel barrier layer 215 that consists of MgO or the like, a magnetic layer (free layer) 214, and an antiferromagnetic layer (not illustrated) consisting of PtMn or IrMn or the like are chiefly laminated on a substrate W. Note that for the constituent material of the magnetic layers 214 and 216, it is possible to adopt for example FePt, TbFeCo, Co/Pd, Fe/EuO, Co/Pt, Co/Pd, CoPtCr—SiO₂, CoCrTaPt, CoCrPt or the like. The tunnel junction element 210 is actually stacked with functional layers other than the aforementioned to become a multilayer structure of as many as 15 layers.

The magnetic layer (fixed layer) 214 is a layer that is fixed so that the magnetizing direction is perpendicular to the front surface of the substrate W, and specifically is fixed facing upward with respect to the front surface of the substrate W. On the other hand, the magnetic layer (free layer) 214 is a layer in which the magnetization direction changes with respect to the orientation of the external magnetic field, and can be inverted to parallel or anti-parallel with respect to the magnetization direction of the magnetic layer (fixed layer) 214. As a result of the magnetization direction of the fixed layer 216 and the free layer 214 being parallel or anti-parallel, the resistance value of the tunnel junction element 210 changes. By providing this kind of tunnel junction element 210 in an MRAM (not illustrated), since it is possible to discriminate information of “0”, “1” in the magnetization direction of a magnetic body, it is possible to read and rewrite “1” or “0”.

### (Magnetic Multilayer Film Manufacturing Device)

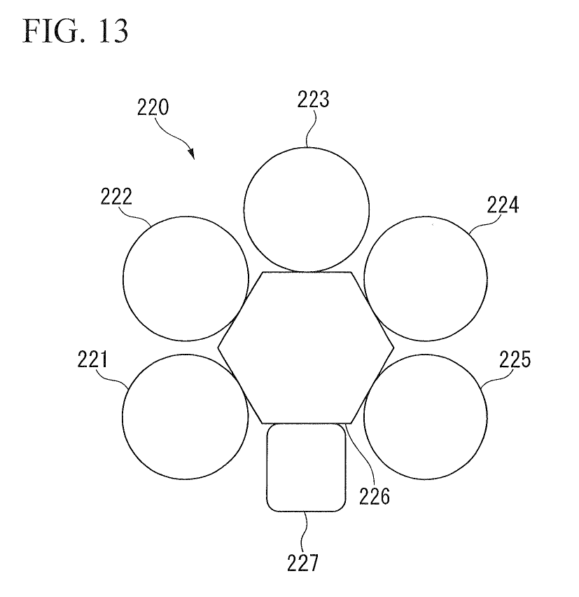

FIG. 13 is a schematic configuration drawing of a magnetic multilayer film manufacturing device according to the present embodiment (hereinbelow referred to as a manufacturing device).

As shown in FIG. 13, a manufacturing device 220 of the present embodiment is one in which a substrate preprocessing chamber 225 and a plurality of sputtering apparatuses 221 to 224 are arranged in a radial manner centered on a substrate conveying chamber 226, and for example is a cluster-type manufacturing device 220 that consistently performs a preprocessing/film formation step of a magnetic multilayer film that constitutes the aforementioned tunnel junction element.

Specifically, the manufacturing device 220 is provided with the substrate preprocessing chamber 225 that performs a preprocessing step of the substrate W, a substrate cassette chamber 227 in which a substrate W prior to film formation is held, a first sputtering apparatus 221 that performs the film formation step of the antiferromagnetic layer, a second sputtering apparatus (sputtering apparatus) 222 that performs the film formation step of the magnetic layer (fixed layer) 216, a third sputtering apparatus 223 that performs the film formation step of the tunnel barrier layer 215, and a fourth sputtering apparatus (sputtering apparatus) 224 that performs the film formation step of the magnetic layer (free layer) 216.

In the aforementioned manufacturing device 220, after the required substrate preprocessing in the substrate preprocessing chamber 225, the magnetic multilayer film of the magnetic layer 216, the tunnel barrier layer 215, the magnetic layer 214, and the like are formed on the substrate W in the sputtering apparatuses 221 to 224. In this way, in the cluster-type manufacturing device 220, it is possible to form the magnetic multilayer film on the substrate W without exposing the substrate W that is supplied to the manufacturing device 220 to the atmosphere. Note that after forming a resist pattern on the magnetic multilayer film and patterning the magnetic multilayer film into a predetermined shape by etching, the tunnel junction element 210 is formed by removing the resist pattern.

### (Sputtering Apparatus)

Here, the second and fourth sputtering apparatuses 222 and 224, which are sputtering apparatuses according to the present embodiment, that perform the film formation steps of the magnetic layers 214 and 216 in the magnetic multilayer film shall be described. Note that since the second and fourth sputtering apparatuses 222 and 224 of the present embodiment have approximately the same constitution, in the following description only the second sputtering apparatus 222 shall be described, and the description of the fourth sputtering apparatus 224 shall be omitted. Also, in the following description, the second sputtering apparatus 222 is described as the sputtering apparatus 222.

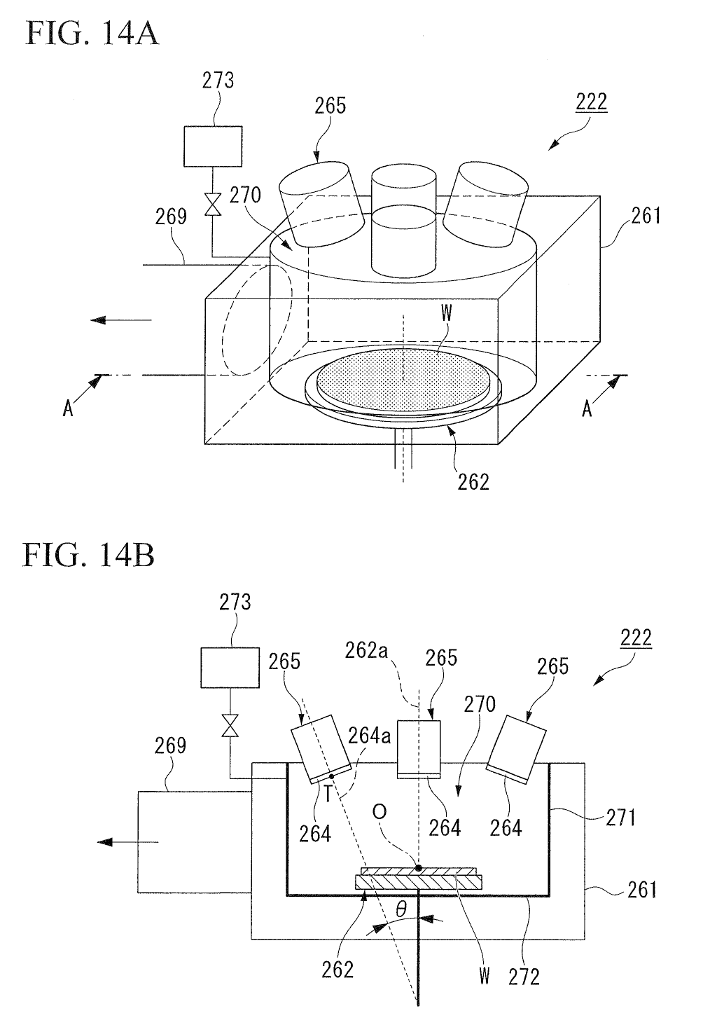

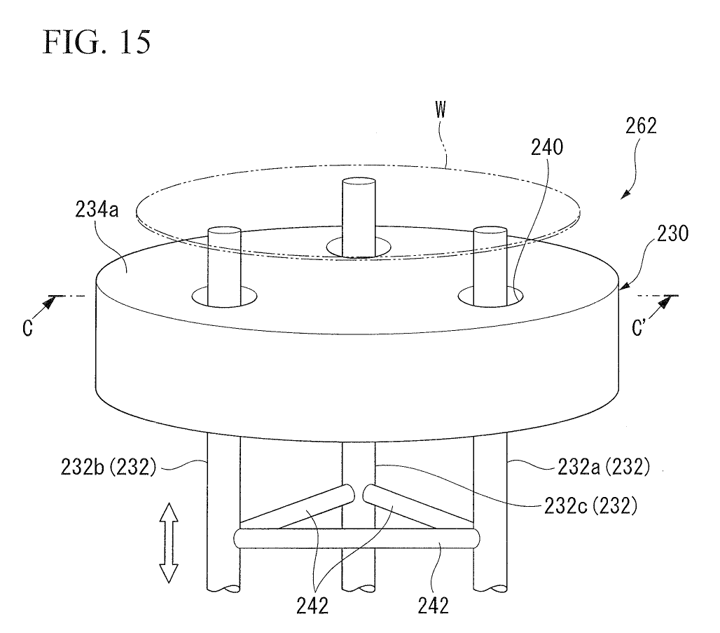

FIG. 14A is a perspective view of the sputtering apparatus according to the present embodiment, and FIG. 14B is a side cross-sectional view along line A-A in FIG. 14A. Also, FIG. 15 is an essential portion cross-sectional view.

As shown in FIG. 14A and FIG. 14B, the sputtering apparatus 222 is constituted by arranging at predetermined positions a substrate stage 262 on which the substrate W is placed and a sputtering cathode 265 that is provided with a target 264 of a film formation material. In the sputtering apparatus 222, the substrate W that has passed through the film formation step of the antiferromagnetic layer in the aforementioned first sputtering apparatus 221 is conveyed from the substrate conveying chamber 226 via a carry-in entrance that is not illustrated.

As shown in FIG. 14B, the sputtering apparatus 222 is provided with a chamber 261 formed in a box shape with a metallic material such as an Al alloy or stainless steel. The substrate stage 262 that mounts the substrate W is provided in the center portion in the vicinity of the bottom surface of the chamber 261. The substrate stage 262 is constituted to be rotatable at a given rotatational frequency with a rotating mechanism not illustrated, with a rotating shaft 262a and the center O of the substrate W coinciding. Thereby, the substrate W that is mounted on the substrate stage 262 can be made to rotate parallel to the surface thereof. Note that as for the substrate W of the present embodiment, for example a silicon wafer is used in which the substrate size is an outer diameter of 300 mm.

A shield plate that consists of stainless steel or the like (a side shield plate 271 and a bottom shield plate 272) are provided so as to encircle the aforementioned substrate stage 262 and the sputtering cathode 265. The side shield plate 271 is formed in a cylindrical shape and is disposed so that the center axis thereof coincides with the rotating shaft 262a of the substrate stage 262. Also, the bottom shield plate 272 is provided from the bottom end portion of the side shield plate 271 to the perimeter edge of the substrate stage 262. The bottom shield plate 272 is formed parallel with the front surface of the substrate W, and is disposed so that the center axis thereof coincides with the rotating shaft 262a of the substrate stage 262.

The space that is surrounded by the substrate stage 262, the bottom shield plate 272 and the side shield plate 271, and the ceiling surface of the chamber 261 is formed as a sputtering process chamber 270 (sputtering chamber) that performs the sputtering process on the substrate W. This sputtering process chamber 270 has an axially symmetric shape, and the axis of symmetry thereof agrees with the rotating shaft 262a of the substrate stage 262. Thereby, it is possible to perform a uniform sputtering process on each portion of the substrate W, and it is possible to reduce variation in the film thickness uniformity and the magnetization direction.

At the periphery of the chamber 261 in the vicinity of the ceiling surface, a plurality of (for example, four) sputtering cathodes 265 are disposed at equally spaced intervals along the circumference of the rotating shaft 262a of the substrate stage 262 (the circumferential direction of the substrate W).

Each sputtering cathode 265 is connected to an external power supply (power supply) that is not shown, and is maintained at a negative electric potential (cathode). Targets 264 have a circular disk shape, and are constituted by a plurality of types of film formation materials that can be laminated on a magnetic multilayer film, such as the film formation material of the magnetic layer 214 described above and a film formation material of a foundation film. Note that the material of each target may be suitably altered. Also, a constitution is also possible so as to dispose targets of the same material (for example, the film formation material of the magnetic layers) on all of the sputter cathodes.

Also, the aforementioned sputtering cathodes 265 are arranged so as to slant with respect to the normal line of the substrate W that is placed on the substrate stage 262. That is, the targets 264 that are attached to the sputtering cathodes 265 are arranged so that a normal line (center axis) 264a that passes through the center point T of the surface thereof slopes for example at an angle θ with respect to the rotating shaft 262a of the substrate W, and the normal lines 264a of the targets 264 and the front surface of the substrate W intersect at the circumferential edge portion of the substrate W.

A sputtering gas supply unit (gas supply unit) 273 that supplies sputtering gas to the inside of the sputtering process chamber 270 is provided outward of the sputtering apparatus 222. This sputtering gas supply unit 273 introduces a sputtering gas such as argon (Ar) to the sputtering process chamber 270. The sputtering gas supply unit 273 is connected to the upper portion of the side shield plate 271 that forms the sputtering process chamber 270, and is constituted so as to supply sputtering gas to the vicinity of the targets 264 in the sputtering process chamber 270. Note that it is also possible to supply a reactant gas such as O₂ from the sputtering gas supply unit 273. Also, a port 269 is provided in the side surface of the chamber 261. This port 269 is connected to a exhaust pump (exhaust unit) that is not illustrated.

### (Substrate Stage)

Next, the aforementioned substrate stage 262 shall be described in greater detail.

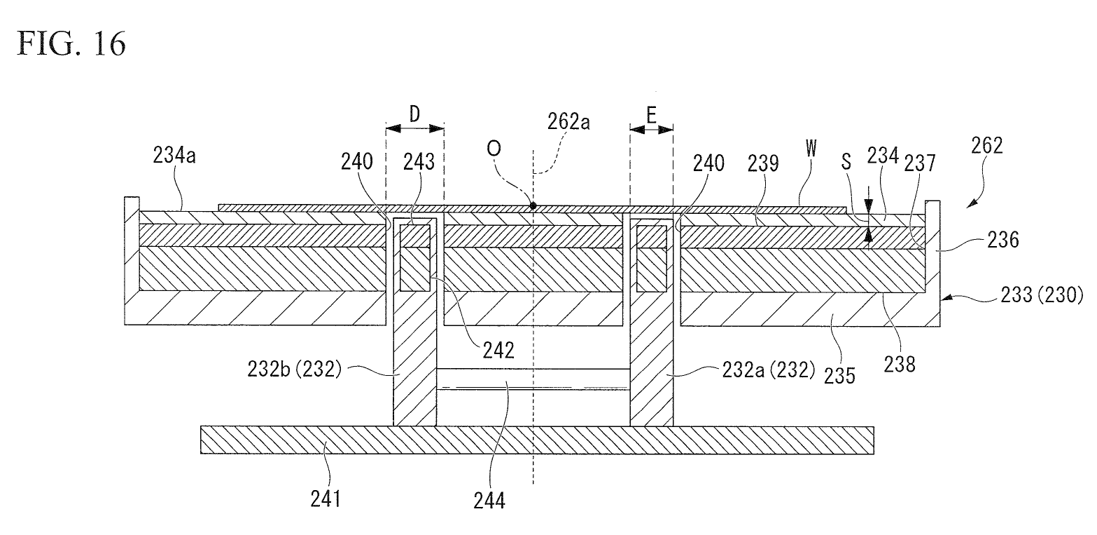

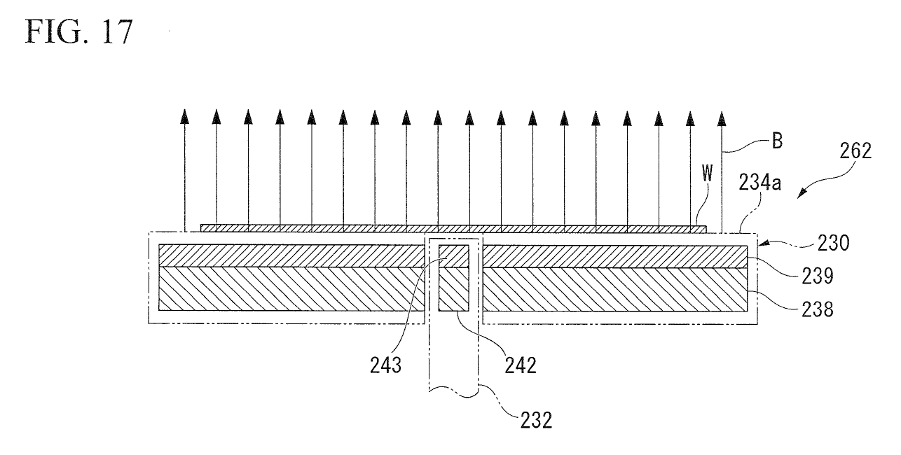

FIG. 15 is a perspective view of the substrate stage, and FIG. 16 is a cross-sectional view that corresponds to the line C-C′ of FIG. 15. Also, FIG. 17 is an explanatory diagram that describes the magnetic lines of force that are generated from the magnetic field applying unit.

As shown in FIG. 15 and FIG. 16, the aforementioned substrate stage 262 is provided with a stage body 230 and elevating pins 232. The stage body 230 is a disc-shaped member made of SUS or the like, and consists of a base portion 232 and a lid portion 234. The base portion 233 is a bottomed cylindrical member in which a cylindrical portion 236 is erected from the outer circumferential edge of a bottom portion 235 that has a disc shape, and the region that is enclosed by the bottom portion 235 and the cylindrical portion 236 is constituted as a housing portion 237 that is concave in cross-sectional view.

A first magnetic field applying unit 238 is housed in the housing portion 237. This first magnetic field applying unit 238 consists of a permanent magnet or the like, and is formed in a disc shape that has an outer diameter that is the same as the inner diameter of the housing portion 237. The first magnetic field applying unit 238 is arranged so that the center axis thereof coincides with the rotating shaft 262a of the substrate stage 262, that is, so that the center axis of the first magnetic field applying unit 238 and the center O of the substrate W coincide. The first magnetic field applying unit 238 serves to apply a perpendicular magnetic field from the back surface side of the substrate W that is placed on the stage body 230 to the front surface of the substrate W, and the internal magnetization direction thereof agrees with the thickness direction (the normal line direction) of the substrate W.

Accordingly, as shown in FIG. 17, the magnetic lines of force B that extend from the first magnetic field applying unit 238 are generated from the N pole (for example, the top surface side) of the first magnetic field applying unit 238, and after crossing approximately perpendicular through the front surface of the substrate W, turn around the outer circumference of the substrate W, and head to the S pole (for example, the bottom surface side). At this time, the magnetic lines of force B that are generated from the first magnetic field applying unit 238 have a perpendicular (normal line direction) magnetic field component with respect to the front surface of the substrate W, and are perpendicularly applied on the entire surface of the front surface of the substrate W.

Also, as shown in FIG. 15 and FIG. 16, the outer diameter of the first magnetic field applying unit 238 is formed to be greater than the outer diameter of the substrate W (for example, 300 mm). Thereby, it is possible for a uniform magnetic field to be applied on the front surface of the substrate W. Note that a suitable design modification is possible provided the outer diameter of the first magnetic field applying unit 238 is equal to or greater than the outer diameter of the substrate. Also, it is preferable that the first magnetic field applying unit be a single-body permanent magnet, but it is also possible to constitute a permanent magnet equal to or greater than the outer diameter of the substrate using a plurality of permanent magnets. For example, a constitution is possible in which a disc-shaped permanent magnet is arranged in the center, and a plurality of annular permanent magnets are arranged so as to encircle the surrounding area. In this case, it is preferable that the interval between each permanent magnet be 1 mm or less.

A first magnetic body 239 is arranged on the upper surface of the first magnetic field applying unit 238. This first magnetic body 239 is constituted from Fe that is nickel plated or magnetic stainless steel (SUS 430) or the like. The first magnetic body 239 has an outer diameter that is the same as the first magnetic field applying unit 238, and is formed thinner than the first magnetic field applying unit 238.

The lid portion 234 is provided on the upper surface of the first magnetic body 239 so as to cover the first magnetic body 239.

This lid portion 234 is a disc-shaped member whose outer diameter is formed to be the same as the inner diameter of the cylindrical portion 236 in the base portion 233, and is formed with a thickness S of for example 5 mm. Since the lid portion 234 is arranged on the upper surface of the first magnetic body 239 in the housing portion 237, the opening of the housing portion 237 is closed. The upper surface of the lid portion 234 is formed as a flat surface, and is constituted as a substrate mounting surface 234a on which the substrate W is mounted. At the outer circumferential portion of the stage body 230, the end face of the cylindrical portion 236 projects from the top surface position of the lid portion 234.

Between the rotating shaft 262a of the stage body 230 and the outer circumference, a plurality (for example, three) of through holes 240 are formed at equally spaced intervals along the circumferential direction of the stage body 230. Each through hole 240 is a round hole with an inner diameter D of for example 10 mm, and penetrates in the thickness direction (axial direction) of the stage body 230 including the first magnetic field applying unit 238 and the first magnetic body 239.

The plurality (for example, three) of elevating pins 232 (232a to 232c) that are capable of vertical motion in the thickness direction of the stage body 230 are inserted in each through hole 240. Each of the elevating pins 232a to 232c has a cylindrical shape that is installed in an upright manner from an elevating plate 241 that is provided below the stage body 230, and is formed with an outer diameter E of for example 8 mm. By raising and lowering the elevating plate 241, the elevating pins 232a to 232c are raised and lowered at the same time. Each of the elevating pins 232a to 232c is designed to support the underside of the substrate W at the top end surface thereof, and by raising the elevating pins 232a to 232c to cause them to project from the upper surface of the stage body 230, reception of a substrate W that is carried into the chamber 261 and transfer of a substrate W that is to be carried out of the chamber 261 are performed.

Here, a second magnetic field applying unit 242 is built into the distal end portion of each elevating pin 232. This second magnetic field applying unit 242 is one with a cylindrical shape that consists of a permanent magnet, with the thickness thereof being formed to the same thickness of the aforementioned first magnetic field applying unit 238, and the internal magnetization direction agreeing with the internal magnetization direction of the first magnetic field applying unit 238. That is, the magnetic lines of force B that extend from the second magnetic field applying unit 242, similarly to the first magnetic field applying unit 238, are generated from the N pole (for example, the top surface side), and after crossing approximately perpendicularly through the front surface of the substrate W, turn around the outer circumference of the substrate W, and head to the S pole (for example, the bottom surface side).

As shown in FIG. 15 and FIG. 16, a second magnetic body 243 that consists of a material similar to the aforementioned first magnetic body 239 is arranged on the upper surface of the second magnetic field applying unit 242. This second magnetic body 243 has an outer diameter that is the same as the second magnetic field applying unit 242, and is formed with a thickness that is the same as the thickness of the first magnetic body 239.

When the substrate W has been mounted on the substrate mounting surface 234a of the stage body 230, the distal end portions of the elevating pins 232 can be arranged so as to interpose in the through holes 240. That is, the distal end faces of the elevating pins 232 are enabled to be arranged with a gap with the undersurface of the substrate W. At this time, the respective upper end surfaces of the second magnetic field applying unit 242 that is built into the elevating pin 232 and the first magnetic field applying unit 238 that is housed in the stage body 230 can be disposed so as to be positioned on the same plane. Note that the elevating pins 232 can rotate together with the substrate stage 262 by a rotation mechanism of the aforementioned substrate stage 262.

In this way, in the substrate stage 262 of the sputtering apparatus 222 of the present embodiment, in addition to the aforementioned first magnetic field applying unit 238, the second magnetic field applying unit 242 that has the same magnetization direction as the internal magnetization direction of the first magnetic field applying unit 238 is interposed in the through hole 240 of the stage body 230. That is, the magnetic field applying unit 238, 242, which make the thickness direction of the substrate W the magnetization direction, are constituted so as to be arranged along approximately the entire surface of the undersurface side of the substrate W.

Also, the elevating pins 232a to 232c are mutually coupled by a support member 244 on the elevating plate 241 side. This support member 244 is a bar-shaped member that is extended in an orthogonal manner to the axial direction of the elevating pins 232a to 232c. One end of the support member 244 is coupled to the peripheral surface of one elevating pin 232a among the plurality of elevating pins 232a to 232c, and the other end is coupled to the peripheral surface of the elevating pin 232b that is adjacent to the elevating pin 232a, and is thus suspended between the two elevating pins 232a, 232b by both ends thereof. Accordingly, the elevating pins 232a to 232c are respectively coupled by three support members 244, whereby collapse of the elevating pins 232a to 232c in the radial direction is prevented. Note that the support member is not limited to a bar-shaped member.

### (Film Forming Method)

Next, the film forming method by the sputtering apparatus of the present embodiment shall be described. Note that in the following description, of the aforementioned magnetic multilayer film, the film forming method for the magnetic layer 214 by the sputtering apparatus 222 shall chiefly be described.

First, as shown in FIG. 15 and FIG. 16, the substrate W on which antiferromagnetic layer is formed in the first sputtering apparatus 221 is transported to the sputtering apparatus 222. Specifically, first the elevating pins 232 are raised to cause the elevating pins 232 to project from the upper surface of the stage body 230. The substrate W that is transported from the first sputtering apparatus 221 is received by the raised elevating pins 232.

Next, in the state of the undersurface of the substrate W being supported by the distal end faces of the elevating pins 232, the elevating pins 232 are lowered and the substrate W is mounted on the substrate mounting surface 234a of the substrate body 230. At this time, it is preferable to stop the lowering of the elevating pins 232 at a position at which the top end surfaces of the second magnetic field applying unit 242 that are internally installed in the elevating pins 232 and the first magnetic field applying unit 238 that is internally installed in the stage body 230 are on the same plane. When lowering the elevating pins 232, since the magnetic pole of the upper surface side of the first magnetic field applying unit 238 and the magnetic pole of the lower surface side of the second magnetic field applying unit 242 differ, there is a risk of the elevating pins 232 falling over due to the attraction between the magnetic field applying unit 238 and 242. Therefore, by coupling the elevating pins 232a to 232c with the support members 244, it is possible to prevent the collapse of the elevating pins 232a to 232c even in the case of attraction and repulsion occurring between the magnetic field applying unit 238 and 242.

Thereby, there is no hindrance in the movement of the elevating pins 232.

After mounting the substrate W on the substrate mounting surface 234a, the substrate stage 262 is made to rotate at a predetermined rotatational frequency along with the elevating pins 232 by a rotating mechanism. Next, after vacuuming the sputtering process chamber 270 with a vacuum pump, sputtering gas such as argon is introduced from the sputtering gas supply unit 273 to the sputtering process chamber 270. A voltage is applied on the targets 264 from the external power supply that is connected to the sputtering cathodes 265. Thereupon, sputtering gas ions that are excited by the plasma in the sputtering process chamber 270 collide with the targets 264, and particles of a film formation material fly out from the targets 264 and adhere to the substrate W. By the above, the magnetic layer 214 is formed on the front surface of the substrate W (refer to FIG. 12). At that time, by generating a high-density plasma in the vicinity of the targets 264, it is possible to speed up the film formation process.

In the present embodiment, in the film formation step of the magnetic layer 214, film formation is performed while generating a perpendicular magnetic field to the front surface of the substrate with the first magnetic field applying unit 238 and the second magnetic field applying unit 242 that are provided around the substrate W.

When a magnetic field is applied by the first magnetic field applying unit 238, the magnetic lines of force B that extend from the first magnetic field applying unit 238 are perpendicularly incident on the front surface of the substrate W. Specifically, the magnetic lines of force B that extend at the from the first magnetic field applying unit 238 are generated from the N pole (the top surface side), and after crossing approximately perpendicularly through the front surface of the substrate W, are incident on the S pole (the bottom surface side) of the first magnetic field applying unit 238. Spattering particles of the film formation material of the magnetic layer 214 that have flow out from the targets 264 comes to be deposited on the front surface of the substrate W while receiving the perpendicular magnetic field to the front surface of the substrate W. At this time, by arranging the first magnetic body 239 on the upper surface of the first magnetic field applying unit 238, since magnetic lines of force are arranged along the center axis inside of the first magnetic body 239, it is possible to improve the perpendicularity of the magnetic lines of force B that extend from the first magnetic field applying unit 238. That is, it is possible to increase the perpendicular magnetic field component to the front surface of the substrate W. Note that the magnetic field that is applied by the magnetic field applying units 238, 242 is preferably 50 (Oe) or more at each portion of the front surface of the substrate W. Also, it is preferable to set the annealing condition in order to improve the perpendicularity of the magnetization direction within the plane of the magnetic layer 214 by the film formation material to be used.

After the magnetic layer 214 is formed, the substrate W is conveyed to the third sputtering apparatus 223. Specifically, in the state of supporting the substrate W by the distal end faces of the elevating pins 232, the elevating pins 232 are raised until the transfer position of the substrate W, and the substrate W is transferred. Here, when raising the elevating pins 232, similarly to when lowering the elevating pins 232 described above, since for example the magnetic pole of the upper surface side of the first magnetic field applying unit 238 and the magnetic pole of the lower surface side of the second magnetic field applying unit 242 differ, there is a risk of the elevating pins 232 falling over due to the attraction between the magnetic field applying units 238 and 242. Therefore, by coupling the elevating pins 232a to 232c with the support members 244, it is possible to prevent the collapse of the elevating pins 232a to 232c even in the case of attraction and repulsion occurring between the magnetic field applying units 238 and 242. Thereby, there is no hindrance of the movement of the elevating pins 232.

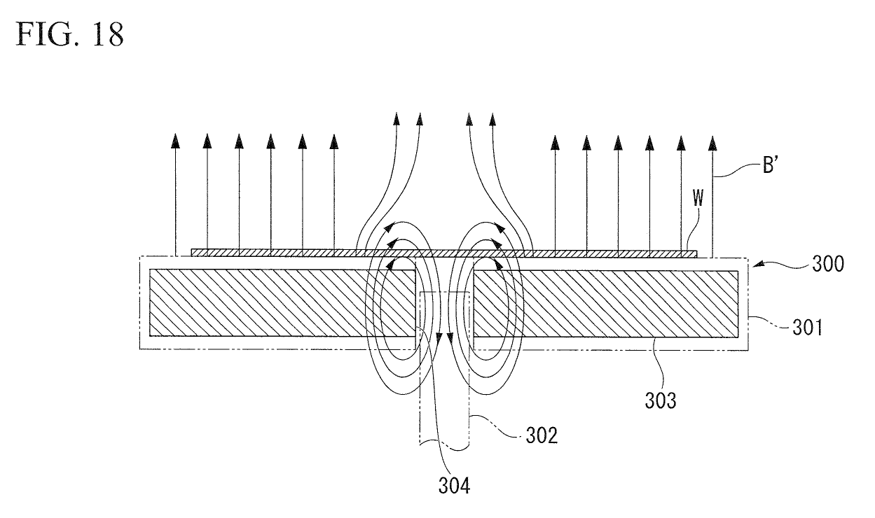

In the conventional art described above, as shown in FIG. 18, as a result of providing the elevating pin 302 in the stage body 301, it is necessary to form the through hole 304 that allows insertion of the elevating pin 302 in the stage body 301 and the magnetic field applying unit 303. Accordingly, a space where the magnetic field applying unit 303 does not exist is formed by the portion of the outer diameter of the through hole 304 in the through hole 304.

In this case, magnetic lines of force B′ that are generated from the magnetic field applying unit 303 cross to the front surface of the substrate W in an approximately perpendicular manner, and an approximately perpendicular magnetic field is applied on the front surface of the substrate W. On the other hand, at the region in the vicinity of the through hole 304, magnetic lines of force B′ that are generated from the magnetic field applying unit 303 extend by curving. In the region closer to the through hole 304, magnetic lines of force B′ that are generated from the magnetic field applying unit 303 pass through the through hole 304 and wrap around to the back surface side of the magnetic field applying unit 303. That is, at the region of the substrate W in the vicinity of the through hole 304, a dispersion occurs in the magnetic field direction that applied on the front surface of the substrate W. Moreover, in the region in the middle of the through hole 304, a problem arises of the risk of a magnetic field being applied that is opposite to that of the region surrounding the through hole 304. As a result, a dispersion occurs within the plane of the magnetizing direction in the magnetic layers 214, 216 (refer to FIG. 12), which serves as a cause for triggering a drop in the MR ratio and a dispersion.

Therefore, in the present embodiment, in addition to the aforementioned first magnetic field applying unit 238 that is housed in the stage body 230, the second magnetic field applying unit 242 that has the same internal magnetization direction as the first magnetic field applying unit 238 is internally installed inside of the elevating pins 232. That is, the second magnetic field applying unit 242 that has the same internal magnetization direction as the first magnetic field applying unit 238 is interposed in the through hole 240 of the first magnetic field applying unit 238. When a magnetic field is applied on the front surface of the substrate W by the second magnetic field applying unit 242 along with the first magnetic field applying unit 238, magnetic lines of force B that extend from the second magnetic field applying unit 242 are perpendicularly incident on the front surface of the substrate W. Specifically, the magnetic lines of force B that extend from the second magnetic field applying unit 242, similarly to the first magnetic field applying unit 238, are generated from the N pole (the top surface side), and after crossing approximately perpendicularly through the front surface of the substrate W, are incident on the S pole (the bottom surface side) of the second magnetic field applying unit 242.

Among the magnetic lines of force B from the first magnetic field applying unit 238, the magnetic lines of force B that extend from the region in the vicinity of the through hole 240 perpendicularly cross to the front surface of the substrate W by being repelled with the magnetic lines of force that extend from the second magnetic field applying unit 242 interposed in the through hole 240. Also, even at the center region of the through hole 240 on the substrate W, the magnetic lines of force B that extend from the second magnetic field applying unit 242 perpendicularly cross to the front surface of the substrate W. At this time, by arranging the second magnetic body 243 on the upper surface of the second magnetic field applying unit 242, since magnetic lines of force are disposed along the center axis inside of the second magnetic body 243 similarly to the aforementioned first magnetic body 239, it is possible to improve the perpendicularity with respect to the front surface of the substrate of the magnetic lines of force B that extend from the second magnetic field applying unit 242. That is, it is possible to increase the perpendicular magnetic field component to the front surface of the substrate W. As a result, since it is possible to apply a perpendicular magnetic field to the entire surface of the front surface of the substrate W, in the film formation process of the magnetic layer 214, it is possible to perform film formation so that the magnetization direction of the magnetic layer 214 becomes perpendicular to the front surface of the substrate W.

In this way, according to the present embodiment, by providing in the elevating pins 232 the second magnetic field applying unit 242 that has the same internal magnetization direction as the first magnetic field applying unit 238 that is provided in the stage body 230, the second magnetic field applying unit 242 that has the same internal magnetization direction as the first magnetic field applying unit 238 comes to be interposed in the through holes 240 that are formed in the stage body 230. Thereby, it is possible to reduce the space in which the magnetic field applying units 238, 242 do not exist in the through holes 240. Accordingly, it is possible to apply a perpendicular magnetic field with respect to the entire surface of the front surface of the substrate W.

Also, since the magnetic lines of force are arranged along the center axis in the magnetic bodies 239, 243 by arranging the magnetic bodies 39, 43 on the upper surfaces of the magnetic field applying units 238, 242, respectively, it is possible to improve the perpendicularity of the magnetic field that is applied on the front surface of the substrate W.

Moreover, by enabling placement of the upper end surfaces of the first magnetic field applying unit 238 and the second magnetic field applying unit 242 on the same plane during the film formation step, it is possible to improve the perpendicularity of the magnetic field that is applied on the front surface of the substrate W.

That is, by increasing the perpendicular magnetic field component to the front surface of the substrate W, it is possible to further reduce dispersion in the magnetization direction of the magnetic layer 214 during the film formation step of the magnetic layers 214, 216 (refer to FIG. 12).

Here, as shown in FIG. 12, the current situation with the conventional perpendicular magnetic tunnel junction element 210 is that the desired MR ratio as described above is not obtained. A cause of this includes for example the dispersion in the magnetization direction of the magnetic layers 214, 216 not being sufficiently controllable. When conventionally forming a perpendicular magnetization film, since manufacturing is carried out by utilizing only the perpendicular magnetization property of the magnetic layers 214, 216 without applying a magnetic field in the magnetization direction, a problem arises of a dispersion occurring in the magnetization direction of the magnetic layers 214 and 216 that are formed. As a result, in the film formation step of the magnetic layers 214, 216, a dispersion occurs in the magnetization direction of the magnetic layers 214, 216, which serves as a cause for triggering a drop in the MR ratio and a dispersion.

In contrast to this, according to the sputtering apparatus 222 of the present embodiment, since it is possible to apply a perpendicular magnetic field with respect to the entire surface of the front surface of the substrate W, it is possible to perform sputtering film formation while accurately applying a magnetic field that has a perpendicular magnetic field component to the front surface of the substrate W. For that reason, in the film formation step of the magnetic layers 214, 216, it is possible to perform film formation while aligning the magnetization direction of the magnetic layers 214, 216 to be perpendicular to the front surface of the substrate W over the entire surface of the substrate W. Thereby, since it is possible to improve the perpendicularity of the magnetization direction of the magnetic layers 214, 216, it is possible to suppress dispersion in the magnetization direction of the magnetic layers 214, 216. Accordingly, since it is possible to form a magnetic multilayer film with improved uniformity in the magnetization direction of the magnetic layers 214, 216, it is possible to provide a tunnel junction element with a high MR ratio over the entire surface of the substrate W.

Hereinabove, preferred embodiments of the present invention were described with reference to the appended drawings, but needless to say the present invention is not limited to these examples. The constituent elements and combinations shown in the examples given above are merely one example, and various modifications based on design requirements can be made within a range that does not depart from the spirit of the present invention.

For example, in each of the above embodiments, a description was made of the case of using a permanent magnet as the magnetic field applying unit, but it is also possible to adopt a constitution so as to use an electromagnet instead of a permanent magnet.

Also, in each of the above embodiments, a description was made of the case of forming a magnetic layer in the tunnel junction element of the magnetic multilayer film, but it can be adopted for various film formation materials and not just the magnetic layer.

Moreover, in the aforementioned embodiments, a description was given for the case of adopting the substrate stage of the present invention for a sputtering stage, but it is possible to adopt the substrate stage for other than a sputtering stage. For example, it can be adopted for a magnetic field measuring device or the like that applies a magnetic field in a perpendicular manner on the surface of a substrate that is mounted on the substrate stage.

### INDUSTRIAL APPLICABILITY

According to the substrate stage, the sputtering apparatus provided with this substrate stage and the film forming method of the present invention, during for example the formation of a magnetic layer by the sputtering method, it is possible to suppress dispersion in the magnetization direction of the magnetic layer by applying a perpendicular magnetic field to the entire surface of the front surface of the substrate to obtain a high MR ratio.

What is claimed is:

1. A substrate stage that is arranged in a vacuum chamber and that has a substrate mounting surface on which a substrate is mounted, comprising:
a first magnetic field applying unit that applies a magnetic field to the substrate, wherein the internal magnetization direction of the first magnetic field applying unit and the thickness direction of the substrate match.

2. The substrate stage according to claim 1, wherein the first magnetic field applying unit is provided so as to encircle the periphery of the substrate that is mounted on the substrate mounting surface.

3. The substrate stage according to claim 2, wherein the middle of the first magnetic field applying unit can be arranged at the same height as the front surface of the substrate in the normal line direction of the substrate mounting surface.

4. The substrate stage according to claim 1, wherein the first magnetic field applying unit having a size that is equal to or greater than the outer diameter of the substrate is provided on the back surface side of the substrate that is mounted on the substrate mounting surface.

5. The substrate stage according to claim 4, further comprising a first magnetic body that is positioned between the first magnetic field applying unit and the substrate.

6. The substrate stage according to claim 4, further comprising a second magnetic body that is arranged so as to encircle the periphery of the substrate.

7. The substrate stage according to claim 4, further comprising an elevating pin that raises and lowers the substrate with respect to the substrate mounting surface, and a second magnetic field applying unit that is provided in the elevating pin;
wherein the first magnetic field applying unit has a through hole, the elevating pin is inserted in a slidable manner in the through hole; and
the internal magnetization direction of the second magnetic field applying unit and the internal magnetization direction of the first magnetic field applying unit match.

8. The substrate stage according to claim 7, wherein in the state of the substrate being mounted on the substrate mounting surface, the upper end surface of the first magnetic field applying unit and the upper end surface of the second magnetic field applying unit are capable of being arranged on the same plane.

9. The substrate stage according to claim 7, further comprising:
a plurality of the elevating pins;
a support member that mutually couples the elevating pins, wherein the first magnetic field applying unit has a plurality of the through holes and the elevating pins are respectively arranged in the through holes.

10. The substrate stage according to claim 7, further comprising a magnetic body that is positioned between the first magnetic field applying unit and the substrate and between the second magnetic field applying unit and the substrate.

11. A sputtering apparatus comprising:
the substrate stage according to claim 1;
a sputtering cathode that is arranged so as to be inclined with respect to the normal line of a substrate that is mounted on the substrate mounting surface;
a sputtering chamber in which the substrate stage and the sputtering cathode are arranged;
a vacuum exhaust unit that performs vacuum exhaust of the sputtering chamber;
a gas supply unit that supplies a sputtering gas to the sputtering chamber; and
a power supply that applies a voltage on the sputtering cathode.

12. A film forming method that, with respect to a substrate that is mounted on a substrate stage that is arranged in a vacuum chamber and that has a substrate mounting surface on which a substrate is mounted, performs a sputtering process on the front surface of the substrate while applying a magnetic field with a first magnetic field applying unit so that the internal magnetization direction of this first magnetic field applying unit and the thickness direction of the substrate match.

13. The film forming method according to claim 12, wherein the first magnetic field applying unit is provided so as to encircle the periphery of the substrate.

14. The film forming method according to claim 12, wherein the first magnetic field applying unit is provided on the back surface side of the substrate, and has a size that is equal to or greater than the outer diameter of the substrate.

15. The film forming method according to claim 14, applying a magnetic field on the substrate by a second magnetic field applying unit that is provided in an elevating pin that is inserted in a slidable manner in a through hole that is provided in the first magnetic field applying unit and that raises and lowers the substrate with respect to the substrate mounting surface, matching the internal magnetization direction of the first magnetic field applying unit and the internal magnetization direction of the second magnetic field applying unit, and performing a sputtering process on the substrate with the upper end surface of the first magnetic field applying unit and the upper end surface of the second magnetic field applying unit arranged on the same plane.

16. A film forming method that uses the film forming method according to claim 12 to form a perpendicular magnetization film for forming a tunnel junction element.
